(19) United States
(12) Patent Application Publication
(10) Pub. No.: US 2022/0291562 A1
(43) Pub. Date: Sep. 15, 2022

(54) DISPLAY PANEL AND MANUFACTURING METHOD THEREFOR, AND DISPLAY DEVICE

(71) Applicant: KunShan Go-Visionox Opto-Electronics Co., Ltd., Kunshan (CN)

(72) Inventors: Quan LIU, Kunshan (CN); Liangmei ZUO, Kunshan (CN); Zichao TAO, Kunshan (CN); Jinfang ZHANG, Kunshan (CN); Zhenzhen HAN, Kunshan (CN)

(73) Assignee: KunShan Go-Visionox Opto-Electronics Co., Ltd., Kunshan (CN)

(21) Appl. No.: 17/828,647

(22) Filed: May 31, 2022

Related U.S. Application Data
(63) Continuation of application No. PCT/CN2021/090707, filed on Apr. 28, 2021.

(30) Foreign Application Priority Data
Jun. 30, 2020 (CN) 202010620733.0

(51) Int. Cl. G02F 1/1362; H01L 27/32

(52) U.S. Cl. CPC G02F 1/136286; H01L 27/3276

(57) ABSTRACT

A display panel and a display device. The display panel includes: an array substrate; a first signal line group and a second signal line group arranged on the array substrate, the first signal line group including at least an alternating-current signal line, and the second signal line group including a plurality of signal lines which are direct-current signal lines; and a cover plate, arranged on the array substrate and covering at least the first signal line group. On a plane parallel to the cover plate, a projection of the second signal line group does not overlap with a projection of the cover plate. The display panel and the display device can ensure the reliability of the display panel while also realizing a narrow frame design of the display panel.

### CROSS REFERENCE TO RELATED APPLICATIONS

The present application is a continuation of International Application No. PCT/CN2021/090707, filed on Apr. 28, 2021, the PCT application claims the priority of Chinese patent application No. 202010620733.0, entitled “DISPLAY PANEL AND DISPLAY DEVICE,” filed Jun. 30, 2020. Each of which is incorporated by reference herein in its entirety.

### TECHNICAL FIELD

The present disclosure relates to the field of display technology, and in particular, to a display panel and a display device.

### BACKGROUND

Flat display panels such as a liquid crystal display (LCD) panel, an organic light emitting display (OLED) panel, and a display panel using a light emitting diode (LED) device are widely used in various consumer electronic products such as mobile phones, televisions, personal digital assistants, digital cameras, laptops, desktop computers and the like due to advantages of a high image quality, power saving, a thin body and a wide application range, and become a mainstream of display panels. At present, the requirements for a frame of the display panel are getting higher and higher. It is desired that the display panel has an ultra-narrow frame or even no frame. However, the existence of metal traces in the display panel may occupy more space in a non-display area, which is not conducive to the design of a narrow frame.

### SUMMARY

Some embodiments of the present disclosure provide a display panel and a display device, which can ensure the reliability of the display panel while realizing a narrow frame design of the display panel.

In a first aspect, some embodiments of the present disclosure provide a display panel, which includes:
an array substrate;
a first signal line group and a second signal line group arranged on the array substrate, wherein the first signal line group includes at least an alternating-current signal line, and the second signal line group includes a plurality of signal lines which are direct-current signal lines; and
a cover plate, arranged on the array substrate and covering at least the first signal line group; wherein on a plane parallel to the cover plate, a projection of the second signal line group does not overlap with a projection of the cover plate.

In a second aspect, some embodiments of the present disclosure further provide a display device, which includes the display panel described above.

The display panel and the display device provided by the present disclosure have at least following advantages: the cover plate covers the alternating-current signal line, which can ensure that the alternating-current signal line is located at a non-cutting position of the display panel, and prevent the alternating-current signal line from being damaged when cutting the cover plate due to a weak anti-interference ability, thereby ensuring the reliability of the display panel while realizing the narrow frame design of the display panel.

### BRIEF DESCRIPTION OF THE DRAWINGS

FIG. 1 is a schematic structural diagram of a display panel provided by embodiments of the present disclosure.

FIG. 2 is another schematic structural diagram of the display panel provided by the embodiments of the present disclosure.

FIG. 3 is yet another schematic structural diagram of the display panel provided by the embodiments of the present disclosure.

FIG. 4 is one more schematic structural diagram of the display panel provided by the embodiments of the present disclosure.

FIG. 5 is still another schematic structural diagram of the display panel provided by the embodiments of the present disclosure.

FIG. 6 is still another schematic structural diagram of the display panel provided by the embodiments of the present disclosure.

FIG. 7 is still another schematic structural diagram of the display panel provided by the embodiments of the present disclosure.

FIG. 8 is still another schematic structural diagram of the display panel provided by the embodiments of the present disclosure.

FIG. 9 is still another schematic structural diagram of the display panel provided by the embodiments of the present disclosure.

FIG. 10 is still another schematic structural diagram of the display panel provided by the embodiments of the present disclosure.

FIG. 11 is still another schematic structural diagram of the display panel provided by the embodiments of the present disclosure.

FIG. 12 is still another schematic structural diagram of the display panel provided by the embodiments of the present disclosure.

### DETAILED DESCRIPTION

In order to make the objectives, technical solutions and advantages of the present disclosure clearer, the embodiments of the present disclosure will be described clearly and completely with reference to the accompanying drawings in the embodiments of the present disclosure. It is obvious that the described embodiments are only some embodiments of the present disclosure, rather than all embodiments. Based on the embodiments in the present disclosure, all other embodiments obtained by those skilled in the art without creative work are within the protection scope of the present disclosure.

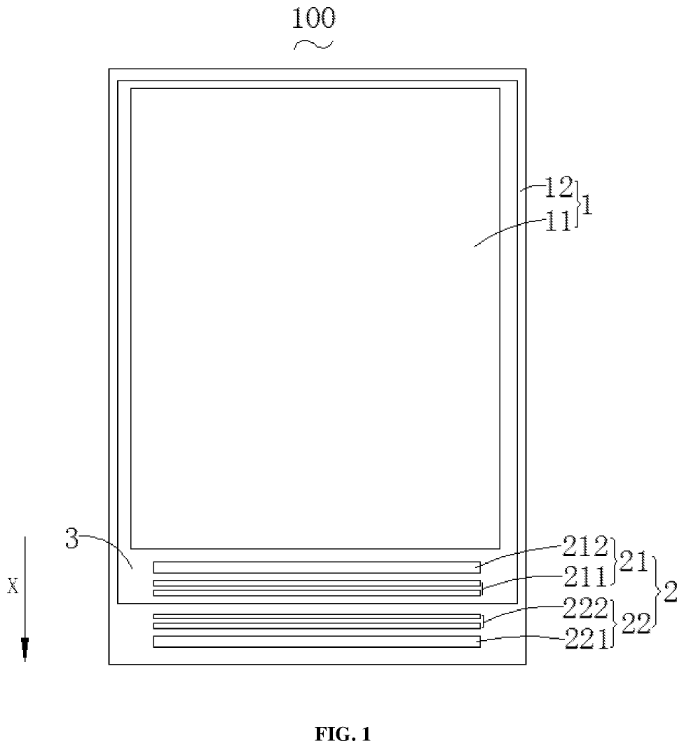

An embodiment of the present disclosure relates to a display panel 100, the specific structure of which is shown in FIG. 1. The display panel 100 including: an array substrate 1, a first signal line group 21 and a second signal line group 22 arranged on the array substrate 1, and a cover plate 3 arranged on the array substrate 1 and covering at least the first signal line group 21. Herein, the first signal line group 21 includes at least an alternating-current signal line 211, and the second signal line group 22 includes a plurality of signal lines which are all direct-current signal lines. On a plane parallel to the cover plate 3, a projection of the second signal line group 22 does not overlap with a projection of the cover plate 3.

It should be noted that the array substrate 1 and the cover plate 3 may be glass substrates or made of flexible materials, such as polyimide (PI), polycarbonate (PC), polyethersulfone (PES), polyethylene terephthalate (PET), polyethylene naphthalate (PEN), polyarylate (PAR) or fibreglass reinforced plastics (FRP) and other polymeric materials. The cover plate 1 may be transparent, semi-transparent or non-transparent to provide support for a formation of a film layer structure arranged on the cover plate 1. The materials of the array substrate 1 and the cover plate 3 may be the same or different, and the materials of the array substrate 1 and the cover plate 3 are not specifically limited in this embodiment.

The signal line is made of metal, which may be a single-layer structure made of molybdenum or a composite structure made of titanium-aluminum-titanium. A metal film of a single-layer structure made of molybdenum has a thickness of 200 nm to 300 nm. A metal film of a laminated titanium-aluminum-titanium structure has a thickness of 700 nm to 800 nm. It can be understood that the material of the signal line is not specifically limited in this embodiment.

In this embodiment, the array substrate 1 includes a display area 11 and a non-display area 12. The first signal line group 21 and the second signal line group 22 are arranged in the non-display area 12, and the cover plate 3 covers the display area 11. Preferably, the signal lines of the first signal line group 21 and the signal lines of the second signal line group 22 are sequentially arranged along an X direction in the non-display area 12.

The cover plate 3 in this embodiment is a cover plate which is cut. When not preparing the display panel 100, the cover plate 3 and the array substrate 1 are the same or similar in size. In a manufacturing process of the display panel 100, it is required to cut the cover plate 3 and expose part of the signal lines arranged on the array substrate 1 to make a FPC and an IC bonding on the exposed signal lines. Due to the demands for a narrow frame design of the display panel 100, it is easy to make a cutting line of the cover plate 3 be located on a side of the alternating-current signal line 211 away from the non-display area 12, resulting in the alternating-current signal line 211 being located outside of the cover plate 3 which is cut, and further resulting in the alternating-current signal line 211 being subjected to an electrostatic interference when cutting the cover plate 3, which causes the alternating-current signal line 211 to be damaged. In this embodiment, the alternating-current signal line 211 is arranged in the non-display area 12, and the cover plate 3 covers the alternating-current signal line 211, which ensure that the alternating-current signal line 211 is covered by the cover plate 3 which is cut, and prevent the alternating-current signal line 211 from being damaged when cutting the cover plate 3 due to a weak anti-interference ability, thereby ensuring the reliability of the display panel 100 while realizing the narrow frame design of the display panel 100.

Referring to FIG. 1, the first signal line group 21 includes a first direct-current signal line 212, and the first direct-current signal line 212 is a VDD signal line. The second signal line group 22 includes a second direct-current signal line 221 and a third direct-current signal line 222. The second direct-current signal line 221 is a VSS signal line and the third direct-current signal line 222 is a PVG signal line. Specifically, the first direct-current signal line 212 is arranged on a side of the alternating-current signal line 211 close to the display area 11. The third direct-current signal line 222 is arranged adjacent to the alternating-current signal line 211. The second direct-current signal line 221 is arranged on a side of the third direct-current signal line 222 away from the display area 11. Since the VDD signal line is connected with the devices in the display area 11, by arranging the first direct-current signal line 212 adjacent to the display area 11, it is avoided that the first signal line 212 is too long to increase the manufacturing difficulty of the display panel 100. It can be understood that the first direct-current signal line 212 shown in FIG. 1 may be a VSS signal line and the second direct-current signal line 221 shown in FIG. 1 may be a VDD signal line. That is, the types of the first signal line 212 and the second signal line 221 are not specifically limited in this embodiment.

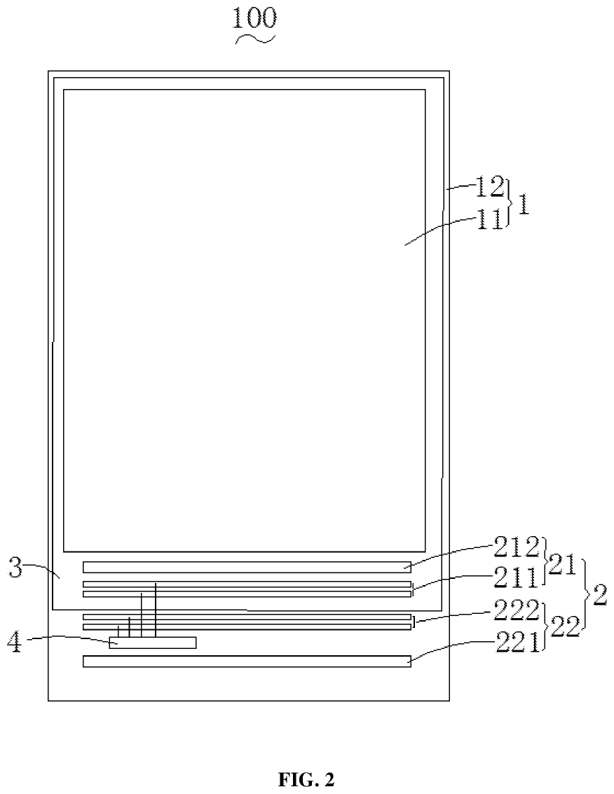

Referring to FIG. 2, the display panel 100 further includes an electrostatic protection circuit 4. Both the third direct-current signal line 222 and the alternating-current signal line 211 are electrically connected with the electrostatic protection circuit 4. It is worth mentioning that the third direct-current signal line 222 and the second direct-current signal line 221 shown in FIG. 2 are arranged in a same layer, and the electrostatic protection circuit 4 includes a first side adjacent to the cover plate 3 and a second side opposite to the first side. By arranging the third direct-current signal line 222 and the second direct-current signal line 221 on the first side and the second side respectively (as shown in FIG. 2, the third direct-current signal line 222 is arranged on the first side and the second direct-current signal line 221 is arranged on the second side; or the third direct-current signal line 222 may also be arranged on the second side and the second direct-current signal line 221 is arranged on the first side), a spacing between the third direct-current signal line 222 and the second direct-current signal line 221 is increased, thereby avoiding a signal crosstalk between the third direct-current signal line 222 and the second direct-current signal line 221, and further improving the reliability of the display panel 100.

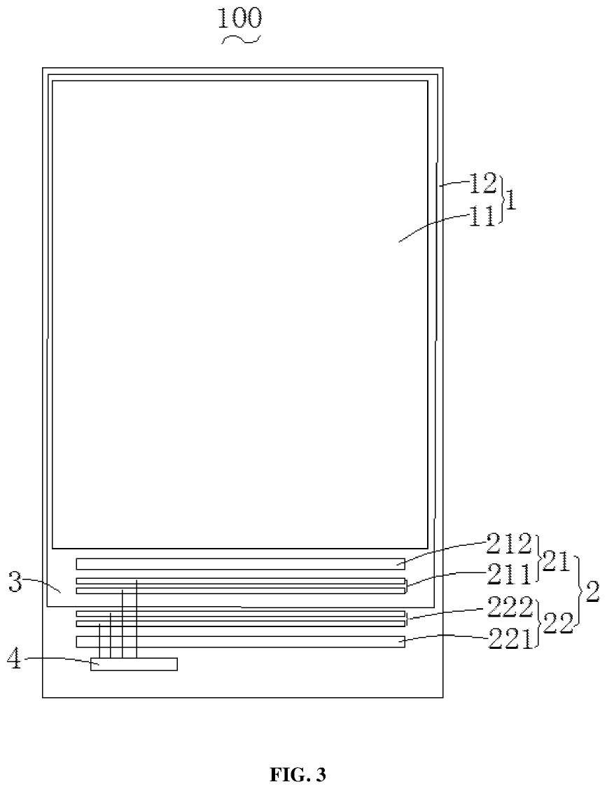

Referring to FIG. 3, the third direct-current signal line 222 and the second direct-current signal line 221 are arranged in different layers, and both the third direct-current signal line 222 and the second direct-current signal line 221 are located on the same side of the electrostatic protection circuit 4. Since the third direct-current signal line 222 and the second direct-current signal line 221 are arranged in different layers, it is difficult to generate the signal crosstalk between the third direct-current signal line 222 and the second direct-current signal line 221, so that a setting position of the electrostatic protection circuit 4 may not be limited.

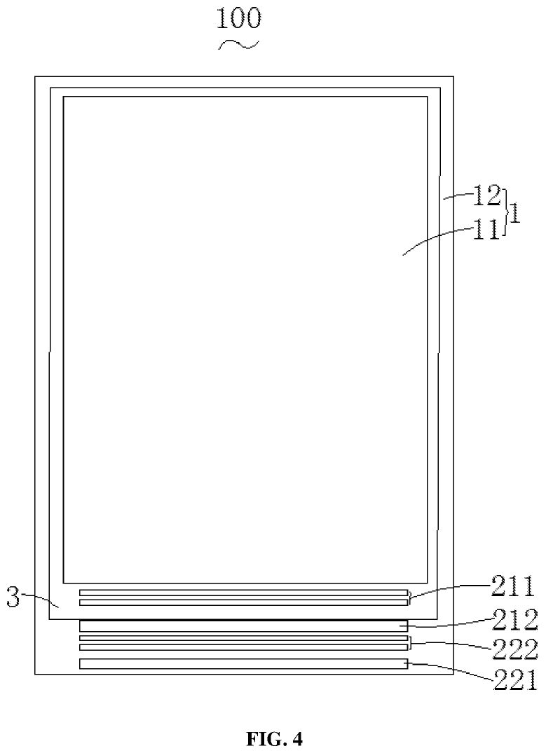

In an alternative embodiment, referring to FIG. 4, the first signal line group 21 includes the alternating-current signal line 211, and the second signal line group 22 includes the first direct-current signal line 212, the second direct-current signal line 221 and the third direct-current signal line 222. The first direct-current signal line 212 is a VDD signal line, the second direct-current signal line 221 is a VSS signal line, and the third direct-current signal line 222 is a PVG signal line. Specifically, the first direct-current signal line 212 is arranged adjacent to the alternating-current signal line 211. The second direct-current signal line 221 is arranged on a side of the first direct-current signal line 212 away from the display area 11. The third direct-current signal line 222 is arranged on a side of the second direct-current signal line 221 away from the display area 11. An arrangement of such structure can ensure that the alternating-current signal line 211 is sandwiched between the array substrate 1 and the cover plate 3, and the alternating-current signal line 211 is prevented from being damaged when cutting the cover plate 3 due to a weak anti-interference ability. It can be understood that the first direct-current signal line 212 may also be the VSS signal line and the second direct-current signal line 221 may also be the VDD signal line. That is, the types of the first direct-current signal line 212 and the second direct-current signal line 221 are not specifically limited in this embodiment.

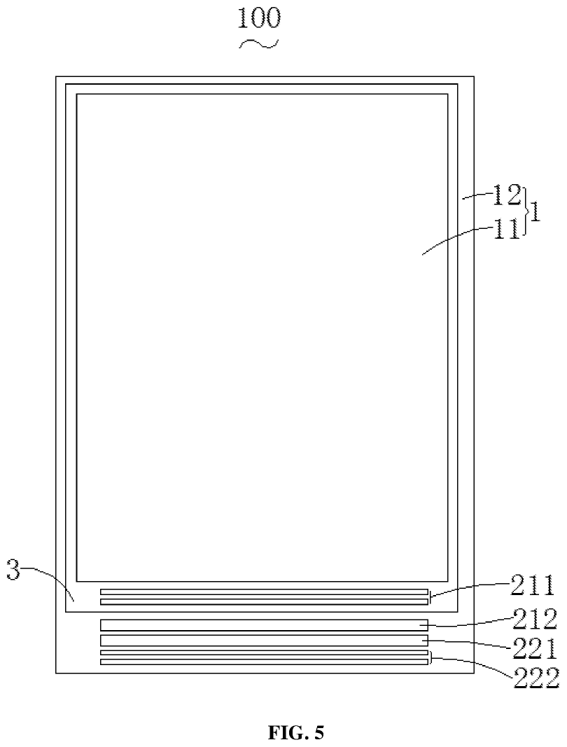

Referring to FIG. 5, the first signal line group 21 includes the alternating-current signal line 211, and the second signal line group 22 includes the first direct-current signal line 212, the second direct-current signal line 221 and the third direct-current signal line 222. The first direct-current signal line 212 is arranged adjacent to the alternating-current signal line 211. The third direct-current signal line 222 is arranged on a side of the first direct-current signal line 212 away from the display area 11. The second direct-current signal line 221 is arranged on a side of the third direct-current signal line 222 away from the display area 11. An arrangement of such structure can ensure that the alternating-current signal line 211 is sandwiched between the array substrate 1 and the cover plate 3, and the alternating-current signal line 211 is prevented from being damaged when cutting the cover plate 3 due to a weak anti-interference ability.

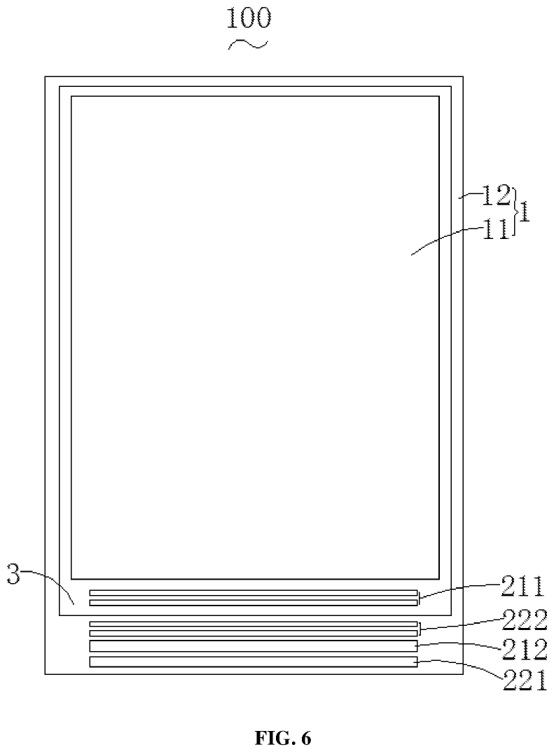

Referring to FIG. 6, the first signal line group 21 includes the alternating-current signal line 211, and the second signal line group 22 includes the first direct-current signal line 212, the second direct-current signal line 221 and the third direct-current signal line 222. The third direct-current signal line 222 is arranged adjacent to the alternating-current signal line 211. The first direct-current signal line 212 is arranged on a side of the third direct-current signal line 222 away from the display area 11. The second direct-current signal line 221 is arranged on a side of the first direct-current signal line 212 away from the display area 11. An arrangement of such structure can ensure that the alternating-current signal line 211 is sandwiched between the array substrate 1 and the cover plate 3, and the alternating-current signal line 211 is prevented from being damaged when cutting the cover plate 3 due to a weak anti-interference ability.

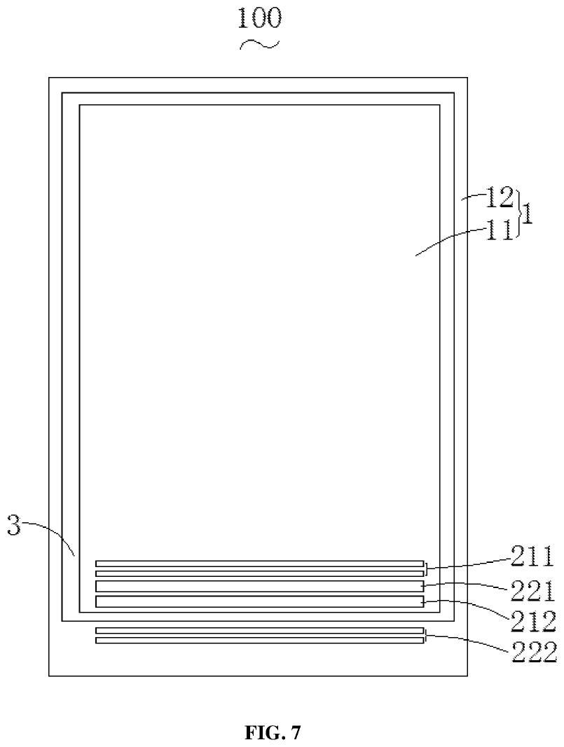

In an alternative embodiment, referring to FIG. 7, the first signal line group 21 includes the first direct-current signal line 212, the second direct-current signal line 221 and the alternating-current signal line 211. The first direct-current signal line 212 is a VDD signal line and the second direct-current signal line is a VSS signal line. The second signal line group 22 includes the third direct-current signal line 222, and the third direct-current signal line 222 is a PVG signal line. Specifically, the first direct-current signal line 212 is arranged adjacent to the third direct-current signal line 222. The second direct-current signal line 221 is arranged on a side of the first direct-current signal line 212 away from the non-display area 12. The alternating-current signal line 211 is arranged on a side of the second direct-current signal line 221 away from the non-display area 12. With an arrangement of such structure, the alternating-current signal line 211 is keeping away from a cutting position of the cover plate 3 as possible, thus further ensuring that the alternating-current signal line 211 may not be damaged when cutting the cover plate 3. It can be understood that the first direct-current signal line 212 may also be the VSS signal line and the second direct-current signal line 221 may also be the VDD signal line. That is, the types of the first direct-current signal line 212 and the second direct-current signal line 221 are not specifically limited in this embodiment.

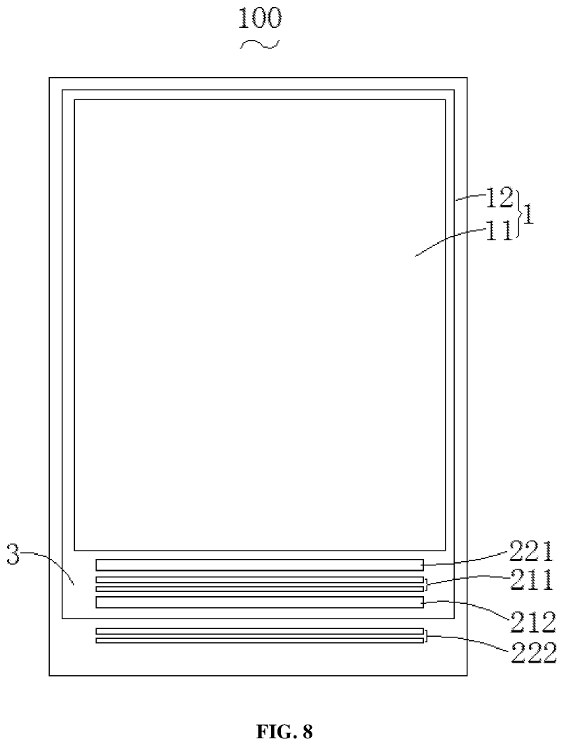

Referring to FIG. 8, the first signal line group 21 includes the first direct-current signal line 212, the second direct-current signal line 221 and the alternating-current signal line 211. The second signal line group 22 includes the third direct-current signal line 222. The first direct-current signal line 212 is arranged adjacent to the third direct-current signal line 222. The alternating-current signal line 211 is arranged on a side of the first direct-current signal line 212 away from the non-display area 12. The second direct-current signal line 221 is arranged on a side of the alternating-current signal line 211 away from the non-display area 12. An arrangement of such structure can ensure that the alternating-current signal line 211 is sandwiched between the array substrate 1 and the cover plate 3, and the alternating-current signal line 211 is prevented from being damaged when cutting the cover plate 3 due to a weak anti-interference ability.

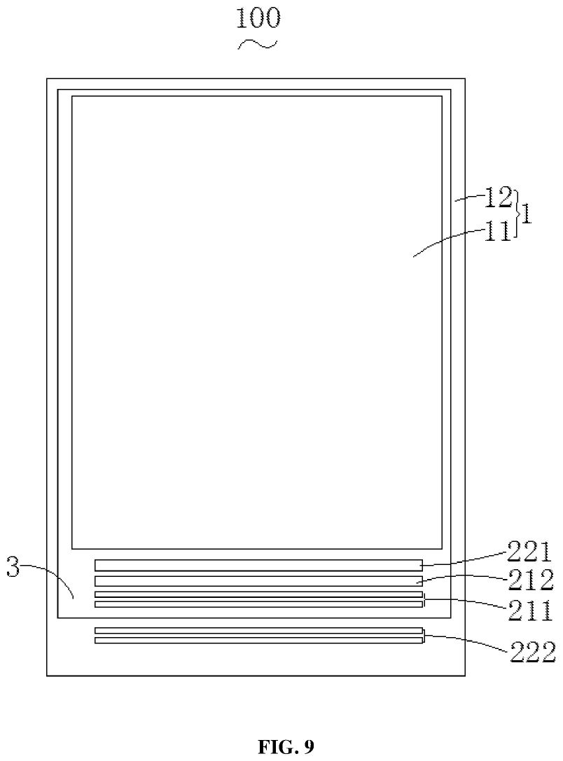

Referring to FIG. 9, the first signal line group 21 includes the first direct-current signal line 212, the second direct-current signal line 221 and the alternating-current signal line 211. The second signal line group 22 includes the third direct-current signal line 222. The alternating-current signal line 211 is arranged adjacent to the third direct-current signal line 222. The first direct-current signal line 212 is arranged on a side of the alternating-current signal line 211 away from the non-display area 12. The second direct-current signal line 221 is arranged on a side of the first direct-current signal line 212 away from the non-display area 12. An arrangement of such structure can ensure that the alternating-current signal line 211 is sandwiched between the array substrate 1 and the cover plate 3, and the alternating-current signal line 211 is prevented from being damaged when cutting the cover plate 3 due to a weak anti-interference ability.

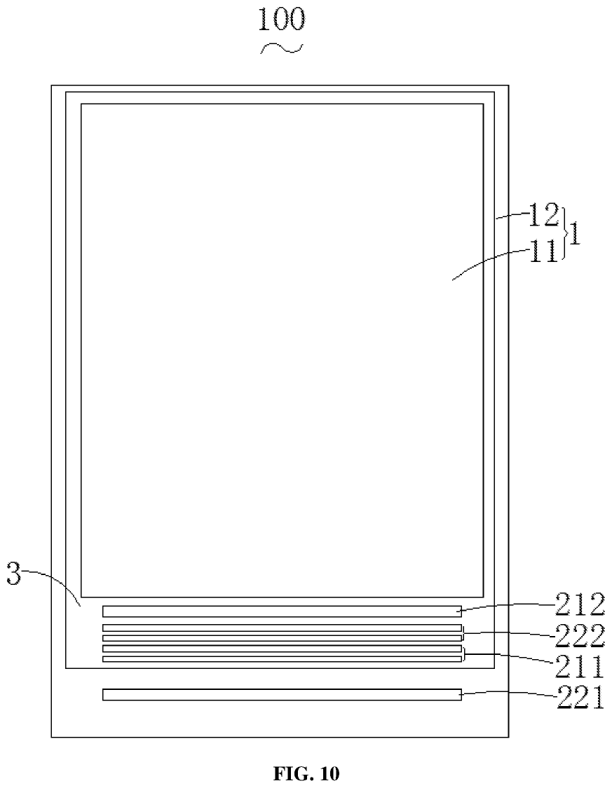

In an alternative embodiment, referring to FIG. 10, the first signal line group 21 includes the first direct-current signal line 212, the third direct-current signal line 222 and the alternating-current signal line 211. The first direct-current signal line 212 is a VDD signal line. The second signal line group 22 includes the second direct-current signal line 221, and the second direct-current signal line 221 is a VSS signal line. Specifically, the alternating-current signal line 211 is arranged adjacent to the second direct-current signal line 221. The first direct-current signal line 212 is arranged on a side of the alternating-current signal line 211 away from the non-display area 12. The third direct-current signal line 222 is arranged on a side of the first direct-current signal line 212 away from the non-display area 12. An arrangement of such structure can ensure that the alternating-current signal line 211 is sandwiched between the array substrate 1 and the cover plate 3, and the alternating-current signal line 211 is prevented from being damaged when cutting the cover plate 3 due to a weak anti-interference ability. It can be understood that the first direct-current signal line 212 may also be the VSS signal line and the second direct-current signal line 221 may also be the VDD signal line. That is, the types of the first direct-current signal line 212 and the second direct-current signal line 221 are not specifically limited in this embodiment. In addition, the setting positions of the first direct-current signal line 212 and the third direct-current signal line 222 may also be exchanged, which can achieve the same technical effect.

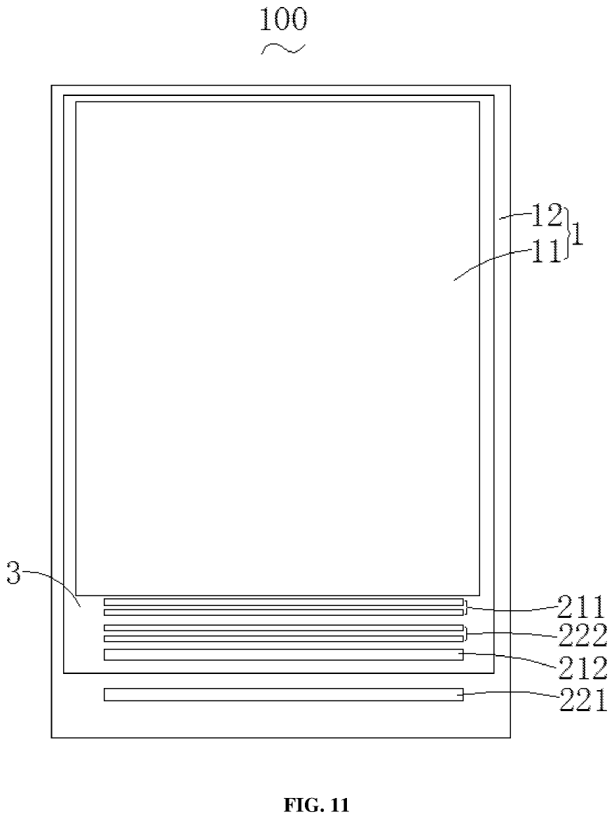

Referring to FIG. 11, the first signal line group 21 includes the first direct-current signal line 212, the third direct-current signal line 222 and the alternating-current signal line 211, and the second signal line group 22 includes the second direct-current signal line 221. The first direct-current signal line 212 is arranged adjacent to the second direct-current signal line 221. The alternating-current signal line 211 is arranged on a side of the first direct-current signal line 212 away from the non-display area 12. The third direct-current signal line 222 is arranged on a side of the alternating-current signal line 211 away from the non-display area 12. An arrangement of such structure can ensure that the alternating-current signal line 211 is sandwiched between the array substrate 1 and the cover plate 3, and the alternating-current signal line 211 is prevented from being damaged when cutting the cover plate 3 due to a weak anti-interference ability. It can be understood that the setting positions of the first direct-current signal line 212 and the third direct-current signal line 222 may also be exchanged, which can achieve the same technical effect.

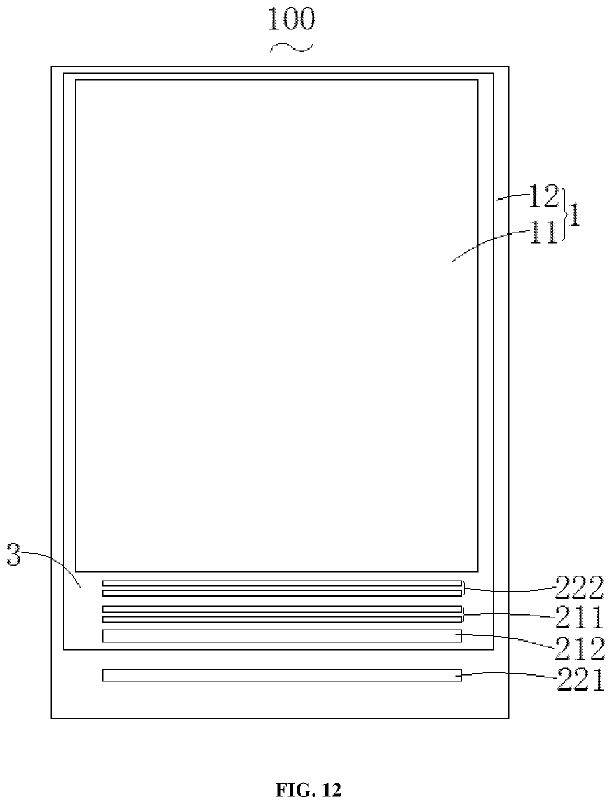

Referring to FIG. 12, the first signal line group 21 includes the first direct-current signal line 212, the third direct-current signal line 222 and the alternating-current signal line 211, and the second signal line group 22 includes the second direct-current signal line 221. The first direct-current signal line 212 is arranged adjacent to the second direct-current signal line 221. The third direct-current signal line 222 is arranged on a side of the first direct-current signal line 212 away from the non-display area 12. The alternating-current signal line 211 is arranged on a side of the third direct-current signal line 222 away from the non-display area 12. It can be understood that the setting positions of the first direct-current signal line 212 and the third direct-current signal line 222 may also be exchanged, which can achieve the same technical effect.

It is worth mentioning that a spacing between adjacent signal lines in this embodiment ranges from 5 microns to 10 microns. With an arrangement of such structure, the signal crosstalk directly generated by adjacent signal lines is avoided, thus further improving the reliability of the display panel 100.

An embodiment of the present disclosure relates to a display device including the display panel described in the above embodiments.

The display device may be used in a smart wearable device (such as a smart bracelet and a smart watch), as well as a smart phone, a tablet computer, a displayer and other devices. Other essential components of the display device should be understood by those of ordinary skill in the art, and will not be repeated here, nor should the essential components are regarded as limitations of the present disclosure.

Those skilled in the art shall appreciate that the aforementioned embodiments are specific embodiments for implementing the present disclosure. In practical applications, however, various changes may be made in the forms and details of the specific embodiments without departing from the spirit and scope of the present disclosure.

What is claimed is:

1. A display panel, comprising:
an array substrate;
a first signal line group, arranged on the array substrate and comprising at least an alternating-current signal line;
a second signal line group, arranged on the array substrate and comprising a plurality of signal lines which are direct-current signal lines; and
a cover plate, arranged on the array substrate and covering at least the first signal line group;
wherein on a plane parallel to the cover plate, a projection of the second signal line group does not overlap with a projection of the cover plate.

2. The display panel according to claim 1, wherein the array substrate comprises a display area and a non-display area, the first signal line group and the second signal line group are arranged in the non-display area, and the cover plate covers the display area.

3. The display panel according to claim 2, wherein the first signal line group and the second signal line group located in the non-display area are sequentially arranged along a preset direction.

4. The display panel according to claim 2, wherein the first signal line group comprises a first direct-current signal line, the first direct-current signal line is arranged on a side of the alternating-current signal line away from the display area, or the first direct-current signal line is arranged on a side of the alternating-current signal line adjacent to the display area; and
the second signal line group comprises a second direct-current signal line and a third direct-current signal line, and the second direct-current signal line or the third direct-current signal line is arranged adjacent to the alternating-current signal line.

5. The display panel according to claim 4, wherein the display panel further comprises an electrostatic protection circuit arranged in the non-display area, and the third direct-current signal line and the alternating-current signal line are electrically connected with the electrostatic protection circuit.

6. The display panel according to claim 5, wherein the third direct-current signal line and the second direct-current signal line are arranged in a same layer; and
the electrostatic protection circuit comprises a first side adjacent to the cover plate and a second side opposite to the first side, and the third direct-current signal line and the second direct-current signal line are respectively located on the first side and the second side.

7. The display panel according to claim 5, wherein the third direct-current signal line and the second direct-current signal line are arranged in different layers, and the third direct-current signal line and the second direct-current signal line are located on a same side of the electrostatic protection circuit.

8. The display panel according to claim 2, wherein the first signal line group comprises a first direct-current signal line and a second direct-current signal line, and the second signal line group comprises a third direct-current signal line; and
the alternating-current signal line is arranged between the first direct-current signal line and the second direct-current signal line, or the alternating-current signal line is arranged adjacent to the display area, or the alternating-current signal line is arranged away from the display area.

9. The display panel according to claim 4, wherein the first direct-current signal line and the second direct-current signal line are a VSS signal line and a VDD signal line, respectively.

10. The display panel according to claim 2, wherein the second signal line group comprises a first direct-current signal line, a second direct-current signal line and a third direct-current signal line;
the first direct-current signal line is a VDD signal line, the second direct-current signal line is a VSS signal line and the third direct-current signal line is a PVG signal line; and
the first direct-current signal line is arranged adjacent to the alternating-current signal line, the second direct-current signal line is arranged on a side of the first direct-current signal line away from the display area, and the third direct-current signal line is arranged on a side of the second direct-current signal line away from the display area.

11. The display panel according to claim 2, wherein the second signal line group comprises a first direct-current signal line, a second direct-current signal line and a third direct-current signal line;
the first direct-current signal line is a VDD signal line, the second direct-current signal line is a VSS signal line and the third direct-current signal line is a PVG signal line; and
the first direct-current signal line is arranged adjacent to the alternating-current signal line, the third direct-current signal line is arranged on a side of the first direct-current signal line away from the display area, and the second direct-current signal line is arranged on a side of the third direct-current signal line away from the display area.

12. The display panel according to claim 2, wherein the second signal line group comprises a first direct-current signal line, a second direct-current signal line and a third direct-current signal line;
the first direct-current signal line is a VDD signal line, the second direct-current signal line is a VSS signal line and the third direct-current signal line is a PVG signal line; and
the third direct-current signal line is arranged adjacent to the alternating-current signal line, the first direct-current signal line is arranged on a side of the third direct-current signal line away from the display area, and the second direct-current signal line is arranged on a side of the first direct-current signal line away from the display area.

13. The display panel according to claim 2, wherein the first signal line group comprises a first direct-current signal line and a third direct-current signal line, and the first direct-current signal line is a VDD signal line; the second signal line group comprises a second direct-current signal line, and the second direct-current signal line is a VSS signal line; and
the alternating-current signal line is arranged adjacent to the second direct-current signal line, the first direct-current signal line is arranged on a side of the alternating-current signal line away from the non-display area, and the third direct-current signal line is arranged on a side of the first direct-current signal line away from the non-display area.

14. The display panel according to claim 2, wherein the first signal line group comprises a first direct-current signal line and a third direct-current signal line, and the first direct-current signal line is a VDD signal line; the second signal line group comprises a second direct-current signal line, and the second direct-current signal line is a VSS signal line; and
the first direct-current signal line is arranged adjacent to the second direct-current signal line, the alternating-current signal line is arranged on a side of the first direct-current signal line away from the non-display area, and the third direct-current signal line is arranged on a side of the alternating-current signal line away from the non-display area.

15. The display panel according to claim 2, wherein the first signal line group comprises a first direct-current signal line and a third direct-current signal line, and the first direct-current signal line is a VDD signal line; the second signal line group comprises a second direct-current signal line, and the second direct-current signal line is a VSS signal line; and
the first direct-current signal line is arranged adjacent to the second direct-current signal line, the third direct-current signal line is arranged on a side of the first direct-current signal line away from the non-display area, and the alternating-current signal line is arranged on a side of the third direct-current signal line away from the non-display area.

16. The display panel according to claim 1, wherein a spacing between adjacent signal lines ranges from 5 microns to 10 microns.

17. The display panel according to claim 8, wherein the first direct-current signal line and the second direct-current signal line are a VSS signal line and a VDD signal line, respectively.

18. The display panel according to claim 1, wherein all of the signal lines in the second signal line group are the direct-current signal lines.

19. A display device comprising the display panel according to claim 1.
